(19) United States
(12) Patent Application Publication
(10) Pub. No.: US 2025/0373226 A1
(43) Pub. Date: Dec. 4, 2025

(54) BULK ACOUSTIC WAVE CAVITY ISOLATION FROM DIE ATTACH MATERIAL OUTGASSING

(71) Applicant: Texas Instruments Incorporated, Dallas, TX (US)

(72) Inventors: Jeff Jerard Canda, San Fernando (PH); John Carlo Molina, Limay (PH); Connie Esteron, Mabalacat (PH)

(21) Appl. No.: 18/680,613

(22) Filed: May 31, 2024

(51) Int. Cl. H03H 9/05; H03H 9/02; H03H 9/10

(52) U.S. Cl. CPC H03H 9/0509; H03H 9/02023; H03H 9/1007

(57) ABSTRACT

An electronic device includes a first die having a first side, a resonator along the first side, and a sidewall extending outward from the first side, the sidewall laterally spaced apart from and encircling the resonator and including a distal end spaced apart from the first side, a second die spaced apart from the first die and having a second side facing the first die, the second side engaging the distal end of the sidewall to seal a cavity defined by portions of the first and second sides and the sidewall, a trench in one of the second side and the distal end of the sidewall, and a die attach material in the trench and adhering the second side to the distal end of the sidewall to prevent outgassing of the die attach material in the cavity.

### BACKGROUND

Bulk acoustic wave (BAW) devices provide a resonator technology with piezoelectric transduction to generate a gigahertz frequency and high-Q resonance for clock circuits, oscillators, sensors and other applications. BAW resonators have advantages with respect to manufacturability, flexibility, frequency stability, low jitter, and reliability under harsh environmental conditions such as shock and vibration compared to quartz or other oscillators for reference or core clocks in high-speed serializer/deserializer (SERDES) used in telecommunications, data and enterprise network, and industrial or other applications. The BAW resonator operates in a cavity between dies with a die attach material (DAM) forming cavity sidewalls. However, the die attach material is polymeric and subject to outgassing inside the chamber, which can adversely impact the accuracy and reliability of the BAW resonator operating frequency.

### SUMMARY

In one aspect, an electronic device includes a first die with a first side, a resonator along the first side, and a sidewall encircling the resonator with a distal end spaced apart from the first side, as well as a second die, a trench, and a die attach material in the trench, where the second die has a second side facing the first die, the second side engaging the distal end of the sidewall to seal a cavity defined by portions of the first and second sides and the sidewall, the trench extends in one of the second side and the distal end of the sidewall, and the die attach material in the trench adheres the second side to the distal end of the sidewall.

In another aspect, a system includes a circuit board and an electronic device with a lead soldered to a conductive feature of the circuit board, as well as first and second dies, and a die attach material in a trench. The first die has a first side, a circuit coupled to the lead, a resonator along the first side, and a sidewall laterally spaced apart from and encircling the resonator and including a distal end spaced apart from the first side. The second die has a second side facing the first die and engaging the distal end of the sidewall to seal a cavity defined by portions of the first and second sides and the sidewall. The trench extends in one of the second side and the distal end of the sidewall, and the die attach material extends in the trench and adheres the second side to the distal end of the sidewall.

In a further aspect, a method of fabricating an electronic device includes forming a sidewall extending outward from a first side of a first die and laterally spaced apart from and encircling a resonator of the first die, the sidewall having a distal end spaced apart from the first side of the first die, forming a trench in one of the distal end of the sidewall and a second side of a second die, forming a die attach material in the trench, and attaching the second side to the distal end of the sidewall to seal a cavity defined by portions of the first and second sides and the sidewall.

### BRIEF DESCRIPTION OF THE DRAWINGS

FIG. 1 is a partial sectional side elevation view taken along line 1-1 in FIG. 1A of an example electronic device with a BAW resonator in a cavity having a die attach material in a trench in a distal end of a sidewall.

FIG. 1A is a top view of the electronic device taken along line 1A-1A in FIG. 1.

FIG. 1B is a partial sectional side elevation view taken along line 1B-1B in FIG. 1C of another example electronic device with a BAW resonator in a cavity having a die attach material in a first trench in a distal end of a sidewall that extends into a second trench of a cap die.

FIG. 1C is a top view of the electronic device taken along line 1C-1C in FIG. 1B.

FIG. 1D is a partial sectional side view illustrating further details of another electronic device implementation with a cap die attached to a cavity sidewall using first and second trenches with angled or tapered sides.

FIG. 2 is a flow diagram of a method of fabricating an electronic device.

FIGS. 3-16 are partial sectional side elevation views showing an electronic device undergoing fabrication processing according to an implementation of the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for case of description in connection with a particular drawing, where such are not to be construed as limiting with respect to the claims. Various structures and methods of the present disclosure may be beneficially applied to an electronic device or apparatus such as an integrated circuit and manufacturing electronic devices. While such examples may be expected to provide various improvements, no particular result is a requirement of the present disclosure unless explicitly recited in a particular claim.

Example electronic devices are illustrated and described hereinafter, which include a bulk acoustic wave resonator in a sealed cavity between dies and laterally encircled by a sidewall structure, where an example upper or cap die is attached to an upper end of the sidewall by a die attach material within a trench. In certain examples, the die attach material adheres the sidewall end to the cap die to seal the cavity with the die attach material separated from the cavity to mitigate or prevent outgassing of the die attach material into the cavity and enhance long term performance and reliability. Example electronic device and systems are shown and described herein in the form of oscillator integrated circuits that provide a clock signal for use in circuitry of a host printed circuit board (PCB), and the BAW resonator-based oscillator circuitry can be a stand alone IC or can be integrated into larger circuits within an IC. Other implementations are possible including resonator circuits such as bulk acoustic wave or surface acoustic wave (SAW) resonators exposed to a cavity between dies with a trench-based engagement structure with die attach material to join a cavity sidewall structure to a cap or BAW die for any number of applications including without limitation oscillator circuitry.

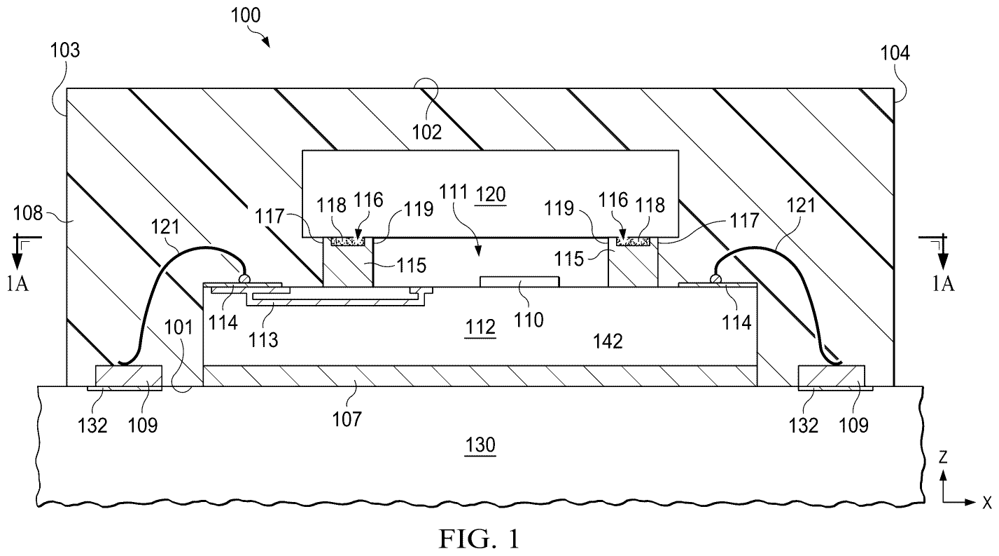

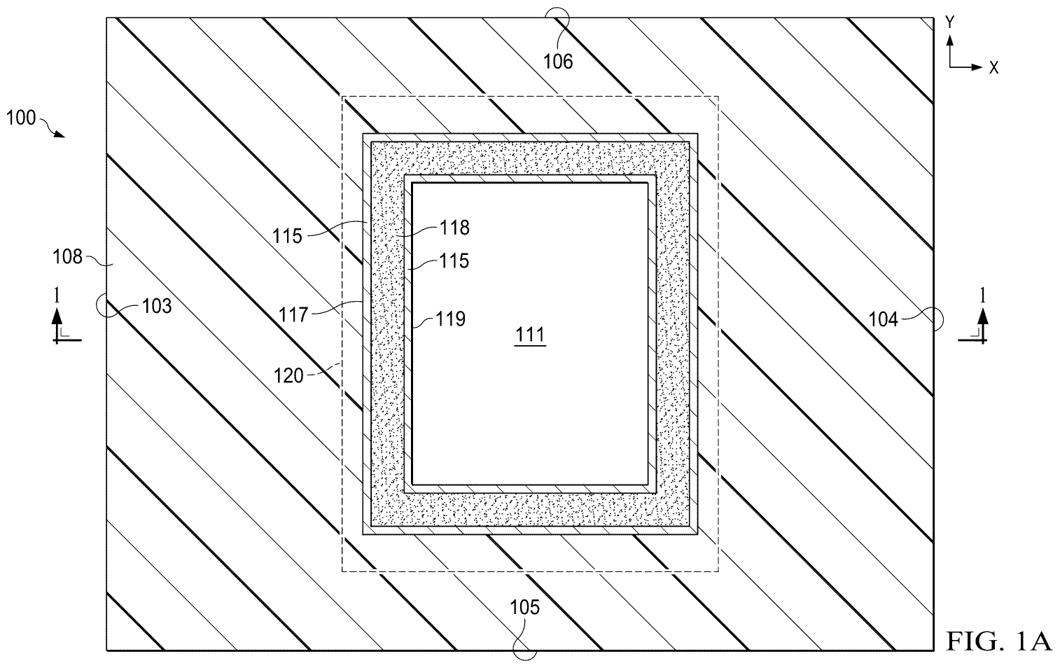

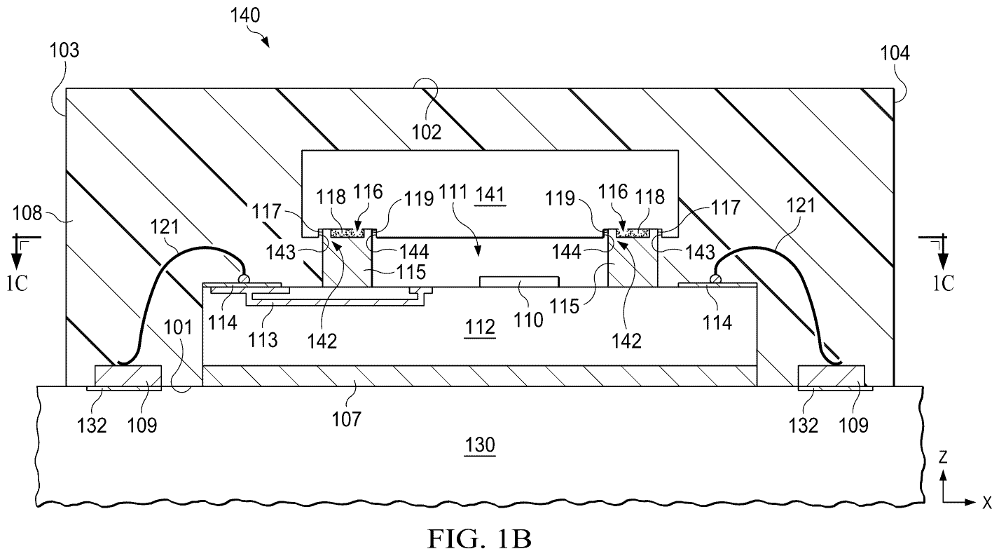

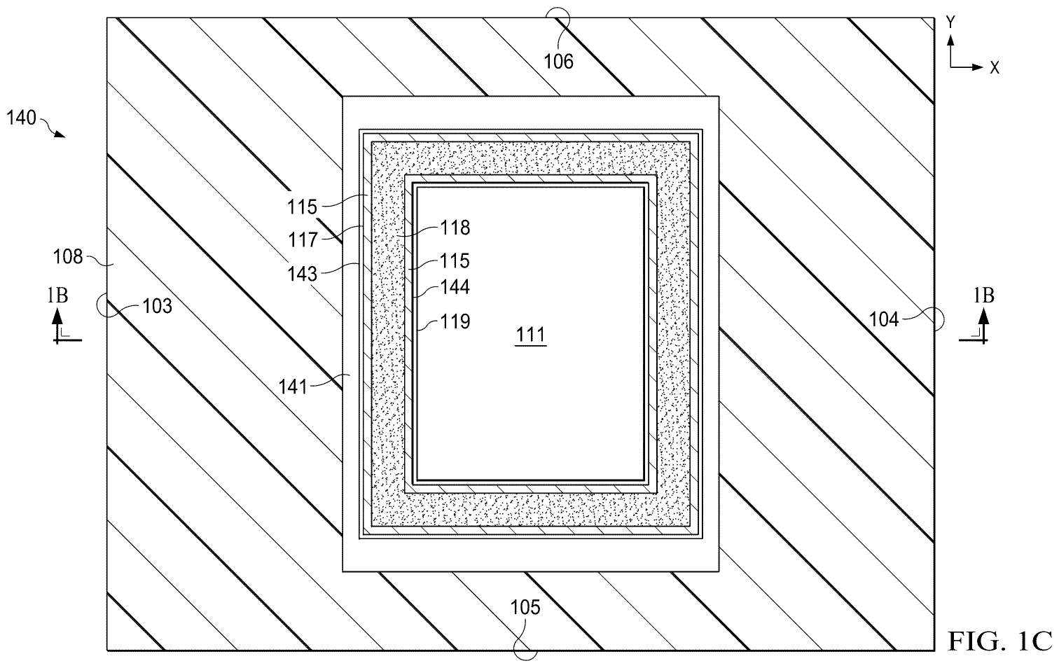

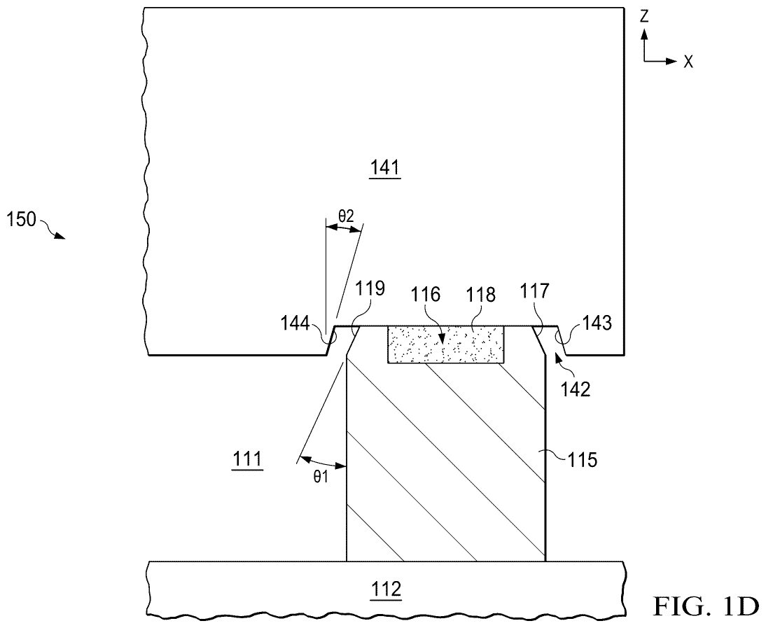

FIGS. 1 and 1A show an example electronic device 100 with a BAW resonator in a cavity having a die attach material in a trench in a distal end of a sidewall. The electronic device 100 and other example electronic devices are illustrated herein in an example position in a three-dimensional space with respective first, second, and third mutually orthogonal directions X (FIGS. 1 and 1A), Y (FIG. 1A), and Z (FIG. 1). The electronic device 100 includes opposite first and second (e.g., bottom and top) sides 101 and 102 (FIG. 1) that are spaced apart from one another along the third direction Z. The electronic device 100 also includes third and fourth sides 103 and 104 that are spaced apart from one another along the first direction Y, and fifth and sixth sides 105 and 106 (FIG. 1A) that are spaced apart from one another along the second direction Y.

The electronic device 100 as a lead frame-based package structure with a die attach pad 107 that extends along the bottom or first side 101, and a molded package structure 108 defines the top or second side 102 as well as the lateral sides 103-106 of the electronic device 100. The device 100 includes conductive leads 109 (FIG. 1) exposed outside the package structure 108 along the first side to provide electrical conductivity to a host circuit board. In one example, the electronic device 100 is an ultra-low jitter, fixed frequency oscillator integrated circuit with a bulk acoustic wave resonator source. In one example, the device 100 can have programmable or factory programmed operation, including output frequency, voltage, output type, etc., and can include additional circuitry (not shown), such as a high-performance fractional frequency divider to produce a clock output signal at a frequency within a specified range. The electronic device 100 includes a BAW resonator to facilitate high-performance clocking, mechanical stability, flexibility, and small package size for reference and core clock applications such as high speed SERDES circuits for telecommunications, data and enterprise network, and industrial applications. In other implementations, the BAW resonator can be used in sensor or filter applications.

As shown in FIG. 1, the electronic device 100 has a BAW resonator 110, such as a module or die having a piezoelectric material in a cavity 111, in which the resonator 110 is attached to a top or first side of a first die 112, which may be referred to as a BAW die. The opposite bottom or second side of the first die 112 is attached to the top side of the die attach pad 107, for example, using die attach adhesive (not shown). In operation, the resonator 110 generates the standing acoustic wave in the bulk of a piezoelectric material, such as quartz (SiO2), aluminum nitride (AlN), zinc oxide (ZnO), etc., between two metal electrodes (not shown) used to produce an electrical signal in the bulk of the piezoelectric material. The resonator 110 is positioned in a platform region on the first side of the first die 112, and the first die 112 can include an etched isolation trench (not shown) that extends into the first side of the first die 112 and circumscribes at least a portion of the platform region on which the resonator 110 is positioned. The first die 112 includes electrical connections 113 between the resonator 110 in the cavity 111 and conductive metal bond pads 114 outside the cavity 111.

A sidewall 115 extends outward along the third direction Z from the first side of the first die 112. The sidewall 115 is laterally spaced apart from and encircles the resonator 110 and the platform region of the first side of the first die 112. The sidewall 115 includes a lower first or proximal end that engages the first side of the first die 112 and an upper second or distal end spaced apart from the first side. In one example, the sidewall 115 is or includes metal, such as plated copper. An inner lateral side of the sidewall 115 extends to the distal end and defines interior sides of the cavity 111 as shown in FIG. 1. The sidewall 115 in one example has an upwardly facing trench 116 that extends into the distal end. The trench 116 has an outer side 117 and an inner side 119, and a die attach material 118 extends in the trench 116.

A second die 120, which can be referred to as a cap die, is attached to the distal end of the sidewall 115 and is spaced apart from the first die 112 along the third direction Z. The second die 120 has a second side that faces the top or first side of the first die 112. The second side engages the distal end of the sidewall 115 to seal the cavity 111 defined by portions of the first and second sides and the sidewall 115, and the die attach material 118 adheres the second side to the distal end of the sidewall 115. In this example, the trench 116 encloses the die attach material 118 and the top of the inner side 119 engages the second side of the second die 120 to seal the cavity 111. The engagement of the second side of the second die 120 to the distal end of the sidewall 115 seals the cavity 111 and the inner side 119 prevents outgassing of the die attach material 118 in the cavity 111. The die attach material 118 adheres the sidewall distal end to the second die 120 to seal the cavity 111 with the die attach material separated from the cavity by the inner side 119 to prevent the die attach material 118 from outgassing into the cavity 111 to mitigate performance degradation of the BAW resonator.

The metal bond pads 114 are attached by bond wires 121 to respective leads 109 to provide electrical connections to the resonator circuitry. The molded package structure 108 covers the bond wires 121, the dies 112 and 120 and the outer side of the sidewall 115 and extends to the lower first side 101 of the electronic device in one example. In another example, the lower or bottom sides of the leads 109 need not be coplanar with the bottom of the package structure 108 and the leads 109 can extend slightly outward from the lower side of the package structure 108 to facilitate soldering to a host circuit board.

FIG. 1 shows a partial view of a system with a circuit board 130 having a conductive feature 132, such as metal pads. The electronic device 100 is operatively attached to the circuit board 130 with the leads 109 soldered to respective conductive feature 132 of the circuit board 130. The circuit board 130 includes other circuitry (not shown) with components connected to the BAW resonator device 100 and circuitry of the first die 112 via the leads 109 and bond wires 121.

The example electronic device 100 of FIGS. 1 and 1A has a trench 116 that extends in the distal end of the sidewall 115. In other examples, a trench can be formed in one or both of the second side of the cap or second die 120 and the distal end of the sidewall 115, with a die attach material 118 in the trench to adhere the second side to the distal end of the sidewall 115. Any suitable die attach material 118 can be used that adheres the distal end of the sidewall 115 to the second side of the second die 120, for example, die bonders, solder alloys, conductive adhesives, nonconductive adhesives, eutectic compounds, metal alloys, ceramics, and polymers. Metal alloys, such as gold-tin or gold-silicon and eutectic alloys can provide high thermal and electrical conductivity but may require high processing temperatures and can be expensive. Ceramic materials, such as silver-filled glass, balance thermal performance, electrical isolation, and cost. Polymers such as epoxy resins filled with silver particles have low cost, are easy to process and can provide good mechanical strength and thermal performance.

FIGS. 1B and 1C show another example electronic device 140 with a BAW resonator 110 in a cavity 111 and a die attach material 118 in a first trench 116 in a distal end of a sidewall 115 with similarly numbered structures and features generally as described above in connection with the electronic device 100 of FIGS. 1 and 1A. In addition, the electronic device 140 has a second trench 142 that extends into the second side of a cap or second die 141 along the third direction Z. In the illustrated implementation, a portion of the distal end of the sidewall 115 extends at least partially into the second trench 142. The second trench 142 in FIG. 1 of the second side of the second die 141 has an outer side 143 and an inner side 144. In this example, the die attach material 118 extends within the first trench 116 at the distal end off the sidewall 115 and adheres the sidewall distal end to the second die 120 to the second side in the second trench 142 to seal the cavity 111 with the die attach material 118 separated from the cavity 111 by the inner side 119 of the distal end. The seal structure helps prevent outgassing of the die attach material 118 into the cavity 111 to mitigate BAW resonator performance degradation in operation of the electronic device 140.

In other examples, the distal end of the sidewall 115 has no trench and the second side of the second die 141 includes a trench 142 having a lateral width (e.g., in the first direction X in the section view of FIG. 1B) that is wider than the corresponding lateral width of the sidewall 115. The die attach material 118 in one implementation extends in the trench 142 and adheres a portion of the distal end of the sidewall 115 to the second die 141. In one example, a portion of the distal end of the sidewall 115 extends into the trench 142 and engages the inner side 144 of the trench 142 to mitigate or prevent outgassing of the die attach material 118 into the cavity 111.

In yet another implementation, the distal end of the sidewall 115 has no trench and the second side of the second die 141 includes a trench 142 having a lateral width (e.g., in the first direction X in the section view of FIG. 1B) that is smaller than the corresponding lateral width of the sidewall 115, and the die attach material 118 extends in the trench 142 and adheres the distal end of the sidewall 115 to the second die 141. In one example, a portion of the distal end of the sidewall 115 extends in the trench 142 and the inner side 144 of the trench 142 engages a portion of the of the sidewall 115 to seal the cavity 111 and mitigate or prevent outgassing of the die attach material 118 into the cavity 111.

In certain implementations, the cavity 111 is completely separated from (e.g., not exposed to) the die attach material 118. In other examples, the cavity 111 can be exposed to a portion of the die attach material 118, but the extent of the exposed die attach material 118 is significantly less than the amount of die attach material exposure in other designs that construct the entire sidewall 115 using polymeric die attach material. The trench-based enclosure of all or a portion of the die attach material 118 and the use of the sidewall structure 115 helps reduce the likelihood and extent of any die attach material outgassing and helps ensure long term stability and reliability of the electronic device 100 and the resonator 110 in the cavity 111.

FIG. 1D shows a partial view of another electronic device 150 with a cap die 141, a BAW resonator 110 in a cavity 111, and a die attach material 118 in a first trench 116 in a distal end of a sidewall 115 with similarly numbered structures and features generally as described above in connection with the electronic device 100 of FIGS. 1-1C. This example includes the first trench 116 in the distal end of the sidewall 115 and a second trench 142 that extends into the second side of the second die 141 and a portion of the distal end of the sidewall 115 extends at least partially into the second trench 142 as described above in connection with FIGS. 1B and 1C. The second trench 142 in the second side of the second die 141 has an outer side 143 and an inner side 144 and the die attach material 118 extends within the first trench 116 at the distal end off the sidewall 115 and adheres the sidewall distal end to the second die 120 to the second side in the second trench 142 to seal the cavity 111.

In the example electronic device 150 of FIG. 1D, moreover, the die attach material 118 is separated from the cavity 111 by the inner side 119 of the distal end. In addition, the sides of the first and second trenches 116 and 142 are tapered at respective non-zero angles to the third direction Z. In other implementations, the sides of only one of the trenches 116 and 142 are tapered at respective non-zero angles to the third direction Z and/or only one of the (inner or outer) sides of the trenches 116 and 142 are tapered at respective non-zero angles to the third direction Z and/or the inner and outer sides of one or both of the trenches 116, 142 can be a different angles with respect to the third direction Z. In the example of FIG. 1D, the first trench 116 has the outer side 117 at a first angle θ1 to the third direction Z and the inner side 119 of the first trench 116 is tapered at the same first angle θ1 to the third direction Z. In another example, one of the sides 117 and 119 can be untapered. In a further example, the sides 117 and 119 of the first trench 116 can be at different non-zero angles to the third direction Z.

In the illustrated example, the outer and inner sides 143 and 144 of the second trench 142 in the second side of the second die 141 are tapered with respect to the third direction Z. In the illustrated example, the inner side 144 is tapered at a second angle θ2 to the third direction Z and the outer side 143 of the second trench 142 is also tapered at the second angle θ2 to the third direction Z. In another example, one of the sides 143 and 144 can be untapered. In a further example, the sides 143 and 144 of the second trench 142 can be at different non-zero angles to the third direction Z.

In the illustrated example, the first and second angles θ1 and θ2 are approximately the same and are less than 45 degrees. In other examples, the first and second angles θ1 and θ2 can be different and/or one or both can be greater than or equal to 45 degrees. The illustrated sides 117, 119, 143 and 144 in FIG. 1D are generally straight, although other tapered implementations are possible, such as stepped or staircase type tapered sides, nonlinear or curvilinear side profiles, etc. or combinations thereof in other examples. The tapered sides 117, 119, 143 and/or 144 can advantageously facilitate alignment of the second die 120, 141 with the first die 112 during installation of the second die on to the sidewall 115, for example, wherein the angled or tapered side of one or both of the trenches (e.g., one or more of the sides 117, 119, 143 and/or 144) can aid in alignment along the first and/or second directions (X and Y) when the Die (e.g., and wafer form) is attached to the BAW die during fabrication.

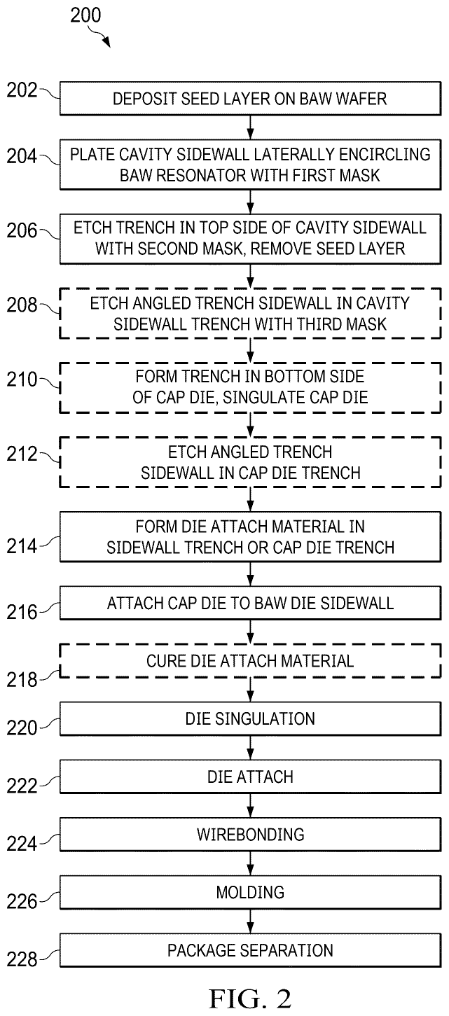

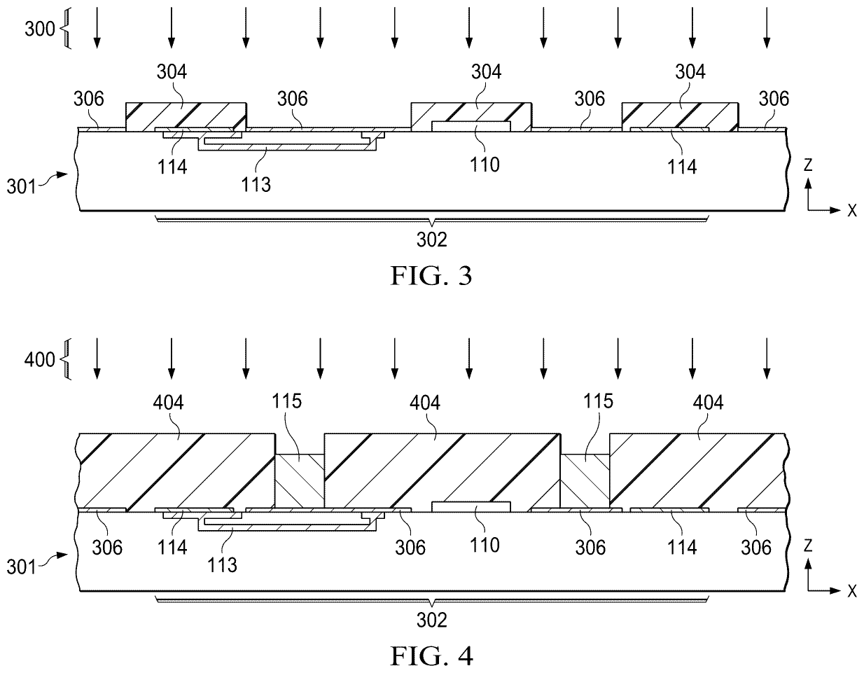

Referring also to FIGS. 2-16, FIG. 2 shows a method 200 of fabricating an electronic device and FIGS. 3-16 show the example electronic device 140 of FIGS. 1B and 1C above undergoing fabrication processing according to various implementations of the method 200. The method 200 includes forming a sidewall at 202-208 in FIG. 2, such as the sidewall 115 in FIGS. 1-1D. In one example, the sidewall 115 is formed of copper by electroplating, and this example includes forming a seed layer at 202 in FIG. 2. FIG. 3 shows one example, in which a sputter deposition process 300 is performed that deposits a copper seed layer 306 on exposed portions of a top side of a semiconductor wafer 301 using a mask 304 to cover certain portions including previously formed bond pads 114 and a previously installed resonator module 110 along the top or second side of the wafer 301. The deposition process 300 in one example forms the copper seed layer 306 that is or includes copper in each of a number of unit areas 302 on the top side of the wafer 301.

The illustrated method continues at 204 in FIG. 2 with plating a sidewall structure that is or includes copper and laterally encircles the BAW resonator 110 in each unit area 302 of the wafer 301. FIG. 4 shows one example, in which an electroplating process 400 is performed with a first plating mask 404 that covers the prospective platform region in each unit area 302 of the wafer 301 and also covers other areas including portions of the seed layer 306 that are not to be included in the subsequently formed sidewall 115. The electroplating process 400 in one example is continued until a sufficient height of plated copper 115 is achieved in the openings of the plating mask 404 to provide a desired height of the subsequently formed cavity 111 (e.g., FIG. 1 above) and define the extent of the distal end of the sidewall 115 along the third direction Z. Any suitable plated material can be used, such as a metal that is or includes copper in one implementation. The plated copper sidewall 115 in one example extends outward from the top or first side of the wafer 301 prior to subsequent die separation to form the above-described first die 112. The plated sidewall structure 115, moreover, is laterally spaced apart from and encircles the resonator 110 in each unit area 302 of the wafer 301.

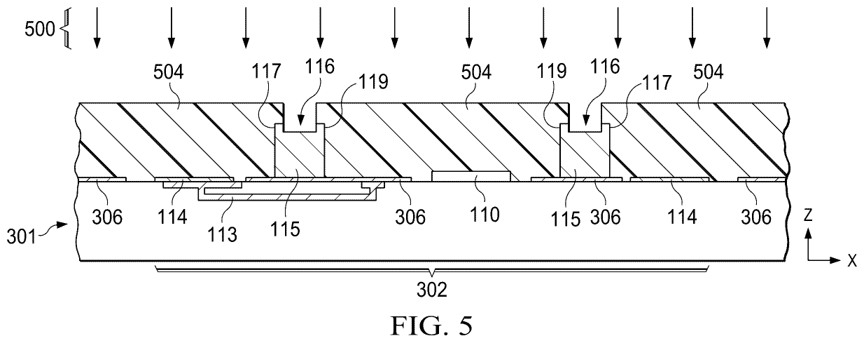

At 206 in FIG. 2, the method 200 continues with etching a trench in the top side of the sidewall using a second mask. FIG. 5 shows one example, in which an etch process 500 is performed using an etch mask 504 that exposes a central portion of the top side of the distal end of the copper plated sidewall 115 and covers other portions of the wafer 301 including covering inner sides 119 and outer sides 117 at the distal end of the sidewall 115. The etch process 500 in one example removes a sufficient amount of material from the distal end of the sidewall 115 to form the trench 116 to a desired trench depth. In one example, the trench depth and the width of the trench are controlled by the respective openings in the mask 504 and the etch process 500 and total etch time to accommodate a desired amount of die attach material 118 to be provided within the trench 116 in the electronic device 140 (e.g., FIG. 1B above). In one example, the remaining portions of the copper seed layer 306 can be removed at 206 and FIG. 2.

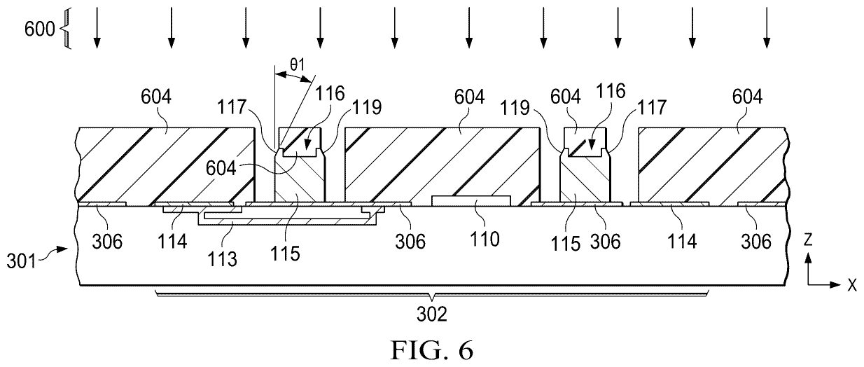

In another implementation, a further trench etch is performed at 208 in FIG. 2 using a third mask in order to provide a tapered side to the etched trench 116. FIG. 6 shows one example, in which a further etch process 600 is performed using another etch mask 604 that covers a previously etched interior portion of the trench 604 and exposes the lateral sides 117 and 119 of the sidewall 115. The second mask 604 and the additional etch process 600 in this example provides tapered sides 117 and 119 of the sidewall 115 (e.g., at the example angle θ1). In another implementation, the optional additional etch process 600 and the processing at 208 in FIG. 2 can be omitted.

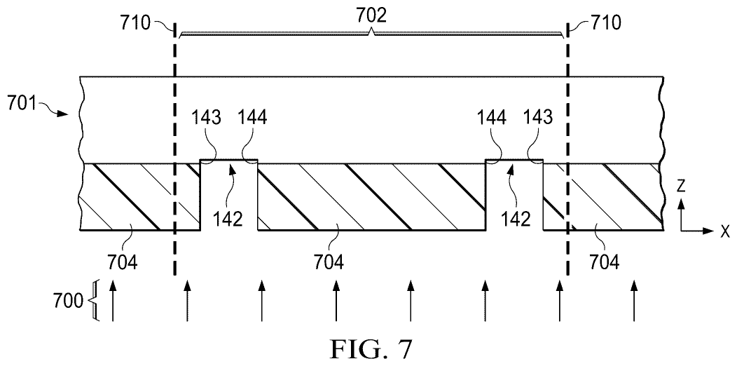

The method 200 continues at 210 in FIG. 2 with forming an optional second trench in the bottom or second side of a second wafer (subsequently separated to form the cap or second die 120, 141 above). FIG. 7 shows one example, in which an etch process 700 is performed on a second wafer 701 using an etch mask 704 with openings corresponding to the prospective second trench 142 in the bottom or second side of the wafer 701. In one example, the etch process 700 is substantially isotropic and forms approximately untapered sides 143 and 144 of the second trench 142 as shown in FIG. 7. In this example, the wafer 701 can then be singulated, for example, using saw cutting, laser cutting, chemical etching, or other suitable die singulation or separation processing along the lines 710 in FIG. 7 to separate individual cap or second dies 141 from the starting wafer 701 after forming the trench 142 in each unit area 301. In another example, the second die (e.g., 120 above) has no second trench, and the second wafer is singulated without trench formation.

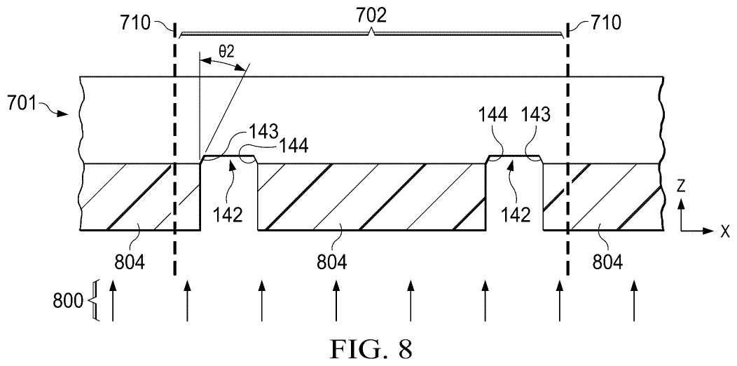

In another example, the second trench 142 is provided with angled or tapered sidewalls 143 and 144, and the method 200 continues at 212 in FIG. 2 with further etching to form the angled trench sidewall in the second wafer 701. FIG. 8 shows one example, in which a further etch process 800 is performed using a second etch mask 804 having slightly wider openings to form further portions of the trench sides 143 and 144 at the non-zero angle (e.g., θ2) to the third direction Z. Further progressive etching can be used to form tapered sides 143 and/or 144 and any desired angle or angles to the third direction Z using multiple masks and progressive etch processes, or other suitable alternate etch processes, such as an anisotropic etching (not shown). In a further example, no tapered sides are desired for the trench 142 and the etch process 800 and the additional etching at 212 in FIG. 2 can be omitted.

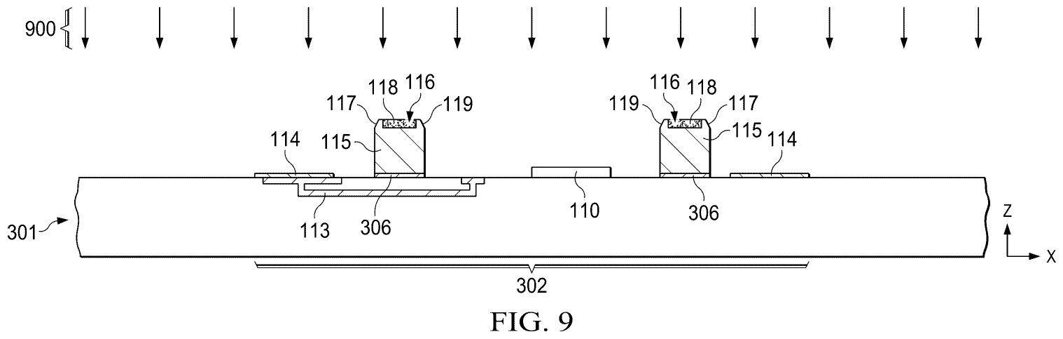

The method 200 continues at 214 in FIG. 2 with die attach processing, including forming the die attach material 118 and the top side trench 116 of the sidewall 115 at the distal ends extending outward from the first side of the prospective first die in each unit area 302 of the first wafer 301. FIG. 9 shows one example, in which a dispensing process 900 is performed that forms the die attach material 118 and the trench 116 of the sidewall 115 in each unit area 302 of the wafer 301. In another example, silk-screening, printing, plating, or other suitable die attach material formation processing can be used at 214 to form the die attach material in the trench 116 that extends into the distal end of the sidewall 115. As discussed above, in another example, the die attach material is instead formed in a trench (e.g., the second trench 142) of a second die or wafer prior to attachment of the second die to the distal end of the sidewall 115. In certain examples, the die attach material 118 is or includes one or more of die bonders, solder alloys, conductive adhesives, nonconductive adhesives, eutectic compounds, metal alloys, ceramics, and polymers.

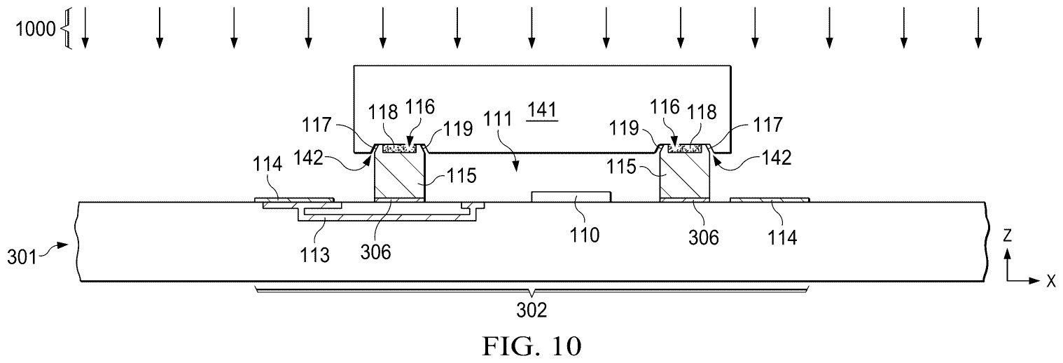

The method 200 in one example continues at 216 in FIG. 2 with cap die attachment that attaches the second die (e.g., 120 or 141) to the distal end of the sidewall 115. FIG. 10 shows one example, in which a die attach process 1000 is performed to attach a second die 141 (e.g., including the second trench 142) in each unit area 302 of the wafer 301. The attachment process 1000 in one example is an automated process using automated pick and place equipment (not shown) to attach an instance of the second die 141 with the first and second trenches 116 and 142 aligned along the first and second directions X and Y, with translation of the second die 141 downward along the third direction Z to engage the distal end of the sidewall 115 with the material of the second dies 141 in the second trench 142 in order to engage the inner side 119 of the sidewall 115 with the second die 141 to seal the cavity 111.

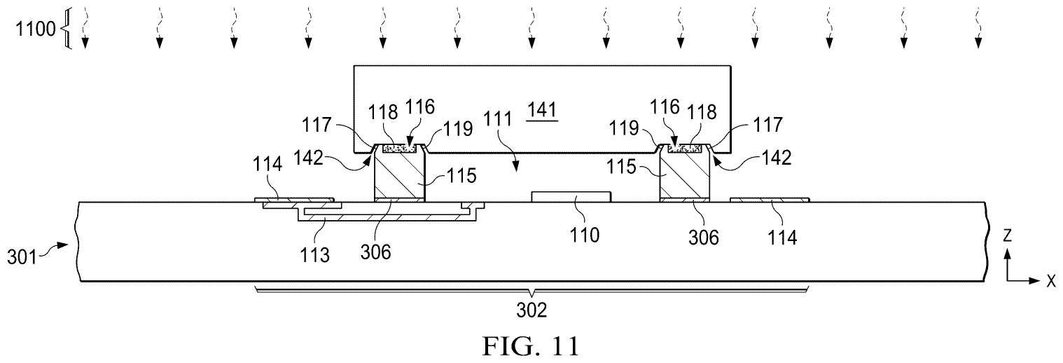

In one example, the method 200 continues at 218 in FIG. 2 with thermal or other adhesive curing to cure the die attach material 118 within the trench 116 to finish the attachment of the second die 141 to the sidewall 115 in each unit area 302. The attachment and curing at 216 and 218 attaches the second side of the second die 141 to the distal end of the sidewall 115 to seal the cavity 111 defined by portions of the first and second sides and the sidewall 115. FIG. 11 shows one example, in which a thermal curing process 1100 is performed that die attach material 118 and adheres the distal end of the sidewall 115 to the second die 141 in the second trench 142 in each unit area 302 of the wafer 301. In another example, ultraviolet light curing can be performed, or other suitable curing process can be performed at 218 in FIG. 2. In another example, no curing process is needed and the processing at 218 can be omitted.

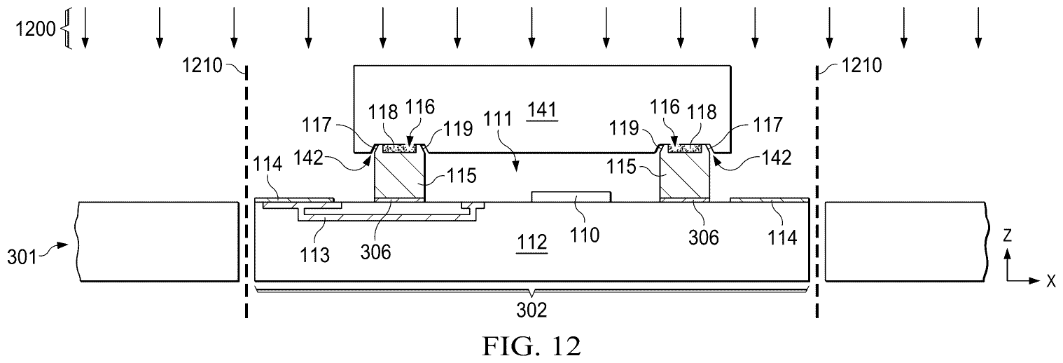

The method 200 continues at 220 in FIG. 2 in one example with die singulation to separate individual die assemblies from the starting wafer structure 301. FIG. 12 shows one example, in which a die singulation or separation process 1200 is performed along the lines 1210 between each adjacent unit area 302 in order to separate individual die assemblies from the wafer structure (e.g., each including an instance of the first die 112 and the second die 141 installed on the corresponding sidewall 115).

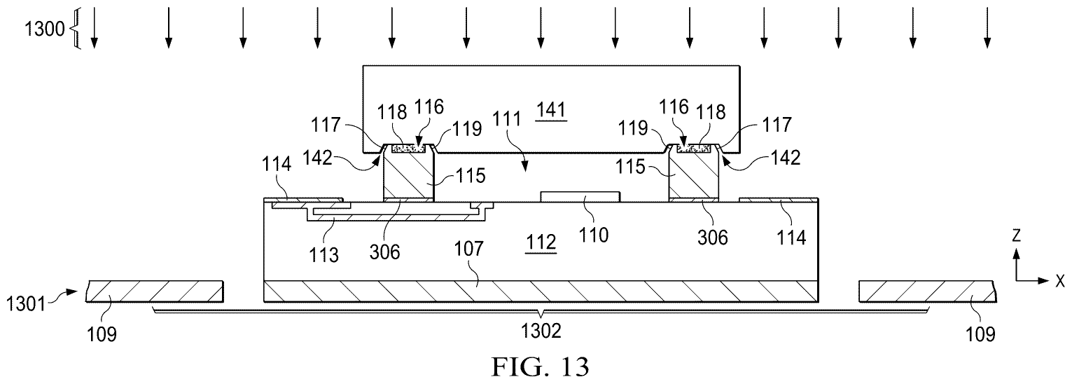

At 222 in FIG. 2, the method 200 continues with die assembly attachment processing. FIG. 13 shows one example, in which a die assembly attach process 1300 is performed using a starting lead frame panel array 1301 with rows and columns of unit areas 1302 each corresponding to a prospective packaged electronic device. In other implementations, different single unit or array structures can be used, such as routable lead frames or multilevel package substrates, etc. (not shown). In the illustrated example, the process 1300 attaches individual instances of the die assembly including the first and second dies 112 and 141 and the sidewall 115 in each unit area 1302 of the lead frame panel array 1301, with the bottom side of the first die 112 attached to the corresponding die attach pad 107 in each unit area 1302, for example, using die attach adhesive (not shown) and automated pick and place equipment (not shown). The attachment process 1300 in one example also includes a die attach adhesive curing step, such as thermal, ultraviolet processing, etc.

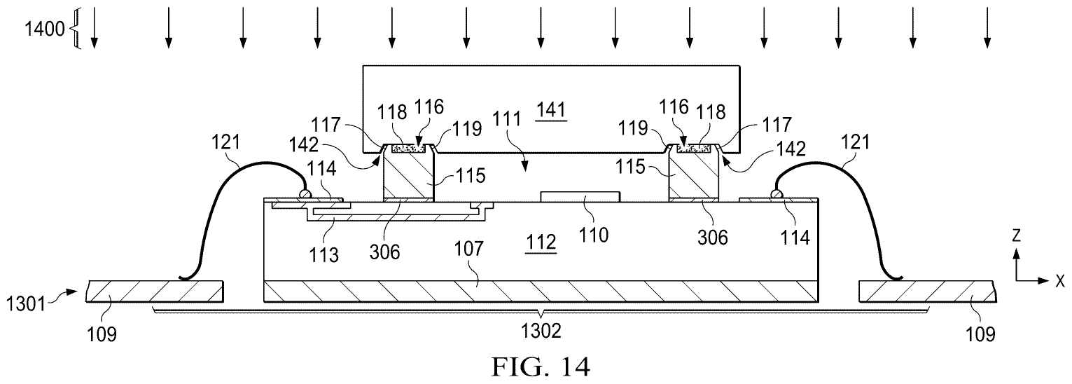

The method 200 continues at 222 in FIG. 2 with electrical connection, such as by wire bonding in the illustrated example. FIG. 14 shows one example, in which a wire bonding process 1400 is performed that forms the bond wires 121 between respective ones of the metal bond pads 114 of the first die 112 and prospective leads 109 in each unit area 1302 of the lead frame panel array 1301.

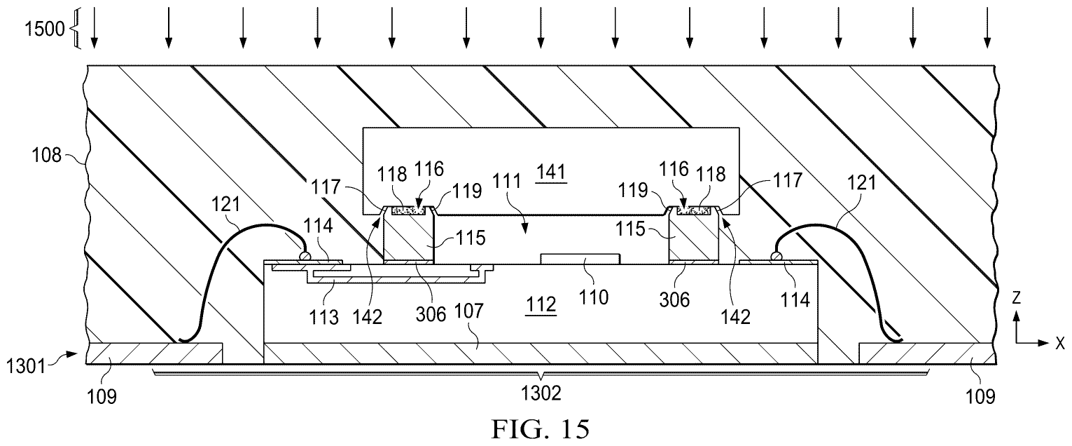

At 226 in FIG. 2, the method 200 continues with package structure formation including a molding processing in the illustrated example. FIG. 15 shows one example, in which a molding process 1500 is performed using a mold (not shown) to form a molded package structure 108 that encloses the dies 112 and 141, the outer portions of the sidewall 115, the upper and lateral portions of the prospective leads 109 and the die attach pad 107, as well as the bond wires 121 in each unit area 1302 of the lead frame panel array 1301. In one example, the molding process 1500 performs a single molded package structure 108 that extends across all rows and columns of the lead frame panel array 1301. In another example, the individual mold cavities are used to form a molded package structure 108 in each unit area 1302. In different examples, the molding equipment can form shared molded package structures 108 that extend across multiple unit areas 1302 of the panel array structure, such as shared molded structures along rows and/or columns of the array.

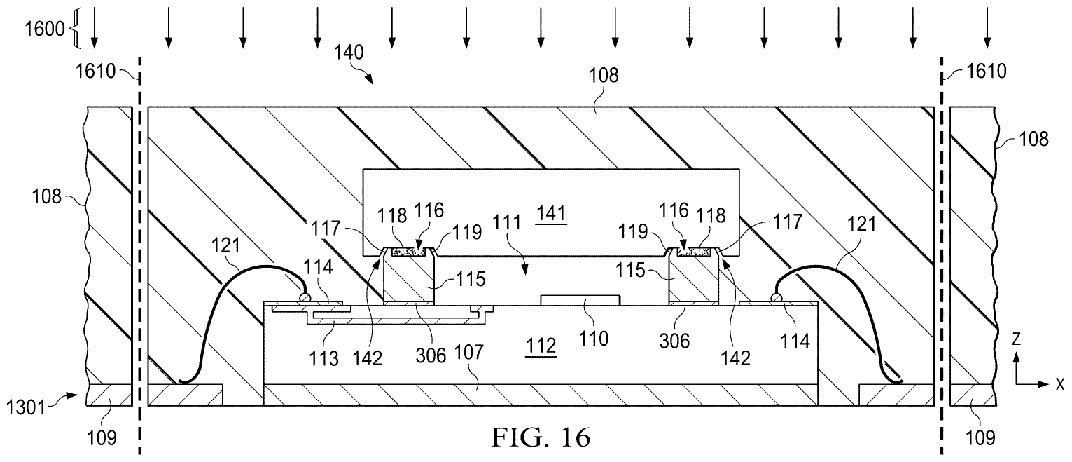

The method 200 continues at 228 in FIG. 2 with package separation. FIG. 16 shows one example, in which a package separation process 1600 is performed that separates individual packaged electronic devices 140 from the lead frame panel array rows and columns along the lines 1610 shown in FIG. 16. Any suitable package separation process 1600 can be used, for example, including saw cutting, laser cutting, chemical etching, etc., or combinations thereof.

The described electronic devices 100, 140, 150 and variants thereof provide BAW resonators 110 in enclosed cavities 111 with cavity sidewalls having die attach material 118 in a trench 142 of the second side of the cap or second die 141 and/or a trench 116 of the distal or top end of the sidewall 115 to reduce or reduce the amount of die attach material 116 that can outgas into the interior cavity 111, and can significantly improve device performance and reliability compared to other designs that openly expose a BAW resonator cavity to die attach material forming cavity sidewalls which leads to outgassing in the long run. Certain described system, electronic device, and method implementations instead provide a cavity sidewall 115, such as a copper or other plated metal structure and a trench (e.g., 116, 142) in either or both of the distal upper and of the sidewall 115 and/or in the lower second side of the second die 120, 141 to enclose the die attach material 118. Example trench-based positioning of the die attach material 118 provides an isolated area in the trench such that the die attach material 118 cannot outgas into the BAW resonator cavity 111. Described examples provide a cost effective solution to mitigate or avoid die attach material outgassing into the BAW resonator cavity 111 and reduce resonator frequency shifting to enhance overall performance accuracy and reliability over time.

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. An electronic device, comprising:
a first die having a first side, a resonator along the first side, and a sidewall extending outward from the first side, the sidewall laterally spaced apart from and encircling the resonator and including a distal end spaced apart from the first side;
a second die spaced apart from the first die and having a second side facing the first die, the second side engaging the distal end of the sidewall to seal a cavity defined by portions of the first and second sides and the sidewall;
a trench in one of the second side and the distal end of the sidewall; and
a die attach material in the trench and adhering the second side to the distal end of the sidewall.

2. The electronic device of claim 1, wherein the trench extends in the distal end of the sidewall.

3. The electronic device of claim 2, wherein the trench is a first trench in the distal end of the sidewall, further comprising a second trench in the second side, wherein a portion of the distal end of the sidewall extends into the second trench.

4. The electronic device of claim 3, wherein:
the first and second dies are spaced apart from one another along a direction; and
one of an outer side of the first trench and an inner side of the second trench is tapered at a non-zero angle to the direction.

5. The electronic device of claim 1, wherein the sidewall includes metal.

6. The electronic device of claim 1, wherein the sidewall includes plated copper.

7. The electronic device of claim 1, wherein the die attach material includes solder.

8. The electronic device of claim 1, wherein the die attach material includes an adhesive.

9. The electronic device of claim 1, wherein:
the first and second dies are spaced apart from one another along a direction; and
a side of the trench is tapered at a non-zero angle to the direction.

10. The electronic device of claim 1, wherein:
the trench extends in the second side; and
a portion of the distal end of the sidewall extends into the trench.

11. The electronic device of claim 1, wherein engagement of the second side to the distal end of the sidewall seals the cavity to prevent outgassing of the die attach material in the cavity.

12. A system, comprising:
a circuit board having a conductive feature; and
an electronic device, including:
a lead soldered to the conductive feature of the circuit board;
a first die having a first side, a circuit coupled to the lead, a resonator along the first side, and a sidewall extending outward from the first side, the sidewall laterally spaced apart from and encircling the resonator and including a distal end spaced apart from the first side;
a second die spaced apart from the first die and having a second side facing the first die, the second side engaging the distal end of the sidewall to seal a cavity defined by portions of the first and second sides and the sidewall;
a trench in one of the second side and the distal end of the sidewall; and
a die attach material in the trench and adhering the second side to the distal end of the sidewall.

13. The system of claim 12, wherein the trench extends in the distal end of the sidewall.

14. The system of claim 13, wherein the trench is a first trench in the distal end of the sidewall, further comprising a second trench in the second side, wherein a portion of the distal end of the sidewall extends into the second trench.

15. The system of claim 12, wherein:
the first and second dies are spaced apart from one another along a direction; and
a side of the trench is tapered at a non-zero angle to the direction.

16. The system of claim 12, wherein:
the trench extends in the second side; and
a portion of the distal end of the sidewall extends into the trench.

17. A method of fabricating an electronic device, the method comprising:
forming a sidewall extending outward from a first side of a first die and laterally spaced apart from and encircling a resonator of the first die, the sidewall having a distal end spaced apart from the first side of the first die;
forming a trench in one of the distal end of the sidewall and a second side of a second die;
forming a die attach material in the trench; and
attaching the second side to the distal end of the sidewall to seal a cavity defined by portions of the first and second sides and the sidewall.

18. The method of claim 17, wherein forming the sidewall includes electroplating a metal sidewall on the first side of the first die using a plating mask.

19. The method of claim 17, wherein forming the trench includes etching the trench into the distal end of the sidewall.

20. The method of claim 17, wherein forming the trench includes etching the trench into the second side of the second die.

21. The method of claim 20, comprising forming an angled side of the trench.

22. The method of claim 17, wherein the trench is a first trench formed in the distal end of the sidewall, further comprising forming a second trench in the second side of the second die.

23. The method of claim 22, comprising forming the die attach material in the first trench.

24. The method of claim 23, comprising forming an angled side of the one of the first and second trenches.
